(19) United States
(12) Patent Application Publication
(10) Pub. No.: US 2017/0342564 A1
(43) Pub. Date: Nov. 30, 2017

(54) PLASMA PROCESSING APPARATUS

(71) Applicant: TOKYO ELECTRON LIMITED, Tokyo (JP)

(72) Inventors: Takahiro HIRANO, Miyagi (JP); Toshihiko IWAO, Miyagi (JP)

(73) Assignee: TOKYO ELECTRON LIMITED, Tokyo (JP)

(21) Appl. No.: 15/535,749

(22) PCT Filed: Dec. 1, 2015
(86) PCT No.: PCT/JP2015/083772

§ 371 Date: Jun. 14, 2017

(30) Foreign Application Priority Data
Dec. 15, 2014 (JP) 2014-253039

(51) Int. Cl. C23C 16/511; H01L 21/3065; H01J 37/32; H01L 21/31

(52) U.S. Cl. CPC C23C 16/511; H01L 21/31; H01L 21/3065; H01J 37/32192; H01J 2237/3321; H01J 2237/334

(57) ABSTRACT

Disclosed is a plasma processing apparatus for performing a plasma processing on a workpiece. The apparatus includes: a processing container that accommodates the workpiece; a dielectric window that is provided to seal an opening in an upper portion of the processing container and transmits microwaves into the processing container; and a slot plate that is provided on an upper surface of the dielectric window and has a plurality of slots formed to radiate the microwaves to the dielectric window. The dielectric window includes a protrusion protruding downward from a lower surface of the dielectric window at a position corresponding to each of the slot, and a width of the protrusion is λ/4±λ/8 with respect to a wavelength λ of the microwaves.

### CROSS-REFERENCE TO RELATED APPLICATIONS

This application is based on and claims priority from Japanese Patent Application No. 2014-253039 filed on Dec. 15, 2014 with the Japan Patent Office, the disclosure of which is incorporated herein in its entirety by reference.

### TECHNICAL FIELD

The present disclosure relates to a plasma processing apparatus for performing a plasma processing on a workpiece.

### BACKGROUND

In the related arts, a plasma processing apparatus using a radial line slot antenna has been known as a plasma processing apparatus that performs a predetermined plasma processing on a workpiece such as, for example, a semiconductor wafer. The radial line slot antenna is disposed on the top of the dielectric window disposed at an opening of the ceiling surface of a processing container in a state where a slow-wave plate is placed on the top of a slot plate having a plurality of slots, and is connected to a coaxial waveguide at a central portion thereof. With such a configuration, the microwaves generated by a microwave generator are radially transmitted in the radial direction by the slow-wave plate via a coaxial waveguide. After generating the circularly polarized wave by the slot plate, the microwaves are radiated from the slot plate into the processing container through the dielectric window. The microwaves make it possible to generate high density plasma having low electron temperature under low pressure in the processing container, and a plasma processing (e.g., a film forming processing or an etching processing) is performed by the generated plasma.

In the plasma processing using microwaves, it has been recognized that there is a so-called mode jump (also referred to as an “electron density jump”). Standing waves of the microwaves are distributed with a specific mode, and the mode is determined by the dimensions of the processing container and the wavelength of the electromagnetic waves. Further, the mode of the standing waves depends on the electron density, and when the electron density is increased by increasing the input power of the microwaves, the absorption of the microwave power is extremely increased with the specific electron density as a boundary, so that the mode is changed. This is a phenomenon called a mode jump, and has a feature that the reflection coefficient of the microwaves is abruptly decreased before and after the electron density is jumped. In addition, when this mode jump occurs, there is a problem that rate variation of the plasma processing is caused.

Therefore, in the plasma processing apparatus described in Patent Document 1, it has been proposed to periodically form concavo-convex portions made of protrusions at a pitch of 7.5 to 30 mm on the surface of the dielectric window on the processing container side. In such a case, as the microwave power increases, the electron density is gradually increased to suppress the mode jump.

### PRIOR ART DOCUMENT

### Patent Document

Patent Document 1: Japanese Patent No. 3787297

### DISCLOSURE OF THE INVENTION

### Problems to be Solved

In order to uniformly perform the plasma processing, it is necessary to make the plasma distribution uniform in the processing container, but a bias in the circumferential direction may occur in the plasma distribution in some cases. As a result of intensive studies by the inventors, it has been found that one of causes of the circumferential bias of the plasma distribution is influenced by the reflected waves from the plasma. The influence of the reflected waves from the plasma will be described in detail later.

In this respect, in the plasma processing apparatus described in Patent Document 1, the influence of the reflected waves from the plasma is not considered at all. Therefore, a circumferential bias may occur in the plasma distribution in the processing container. Thus, there is room for improvement in the plasma processing.

The present disclosure has been made in consideration of the problems, and an object of the present disclosure is to make the plasma distribution uniform in the plasma processing.

### Means to Solve the Problems

In order to achieve the object, the present disclosure provides a plasma processing apparatus for performing a plasma processing on a workpiece. The plasma processing apparatus includes: a processing container that accommodates the workpiece; a dielectric window that is provided to seal an opening in an upper portion of the processing container and transmits microwaves into the processing container; and a slot plate that is provided on an upper surface of the dielectric window and has a plurality of slots formed to radiate the microwaves to the dielectric window. The dielectric window includes a protrusion protruding downward from a lower surface of the dielectric window at a position corresponding to each of the slots, and a width of the protrusion is λ/4±λ/8 with respect to a wavelength λ of the microwaves.

The inventors carried out an experiment in which microwaves are branched using a rectangular waveguide type power splitter and found that the reflected waves from the plasma causes disturbance in the distribution ratio of the microwave power, from the result. Here, in the slot plate of the present disclosure, since a plurality of slots arranged in the circumferential direction may also be regarded as a circumferential power divider, the distribution ratio of each slot is disturbed by reflected waves from the plasma. Thus, it is inferred that the circumferential bias of the plasma distribution is caused. Based on this consideration, the present inventors found that it is necessary to suppress the reflected waves from the plasma to the slots.

As a result of further intensive studies by the inventors, it has been found that absorptivity of microwave power into the plasma may be improved by providing a protrusion having a width of λ/4±λ/8 at a position corresponding to a slot on the lower surface of the dielectric window. In such a case, the reflected waves from the plasma to the slot may be suppressed, and thus, the circumferential bias of the plasma distribution may be suppressed so that the plasma distribution becomes uniform.

Further, according to the present disclosure, the mode jump may be suppressed. As a result of intensive studies by the inventors, it has been found that the mode jump is also one of causes of the circumferential bias of the plasma distribution. Specifically, for example, in a case where there is a slight bias in the electron density for each plasma source, when the input power of the microwaves is increased so as to approach the electron density band where the mode jump occurs, the source with a high electron density jumps first and consumes a lot of power. And, a source with a low electron density jumps late. Then, it was found that the timing of the plasma excitation varied between the sources, causing a circumferential bias of the plasma distribution.

In the present disclosure, as described above, since the absorption of microwave power is improved, the reflection coefficient of the microwaves is reduced. Then, the reflection coefficient of the microwaves is linearly changed with respect to a change in the electron density. Thus, it is possible to suppress a sharp drop of the reflection coefficient, so that a mode jump is suppressed. Therefore, it is possible to further suppress the circumferential bias of the plasma distribution.

According to another aspect, the present disclosure provides a plasma processing apparatus for performing a plasma processing on a workpiece. The plasma processing apparatus includes: a processing container that accommodates the workpiece; a dielectric window that is provided to seal an opening in an upper portion of the processing container and transmits microwaves into the processing container; and a slot plate that is provided on an upper surface of the dielectric window and has a plurality of slots formed to radiate the microwaves to the dielectric window. The dielectric window includes a protrusion protruding downward from a lower surface of the dielectric window at a position where a distance between a center of the protrusion and a center of each of the slots is equal to or less than λ/2 with respect to a wavelength λ of the microwaves.

### Effect of the Invention

According to the present disclosure, the circumferential bias of the plasma distribution may be suppressed in the plasma processing such that the plasma distribution becomes uniform.

### BRIEF DESCRIPTION OF THE DRAWINGS

FIG. 1 is a vertical-sectional view illustrating a schematic configuration of a plasma processing apparatus according to an exemplary embodiment of the present disclosure.

FIG. 2 is a plan view illustrating a schematic configuration of a slot plate.

FIG. 3 is a plan view of a dielectric window when viewed from the bottom.

FIG. 4 is a plan view illustrating a schematic configuration of the dielectric window and the slot plate.

FIG. 5 is an explanatory view illustrating a schematic configuration of protrusions and slots.

FIG. 6 is a graph illustrating the absorptivity of microwave power in a case where the width of the protrusions is changed.

FIG. 7 is a graph illustrating the absorptivity of microwave power in a case where the gap between the protrusions is changed.

FIG. 8 is a graph illustrating the absorptivity of microwave power in a case where the height of the protrusions is changed.

FIG. 9 is a graph illustrating the absorptivity of microwave power in a case where the number of the protrusions is changed.

FIG. 10 is a plan view illustrating a schematic configuration of a slot plate according to another exemplary embodiment.

FIG. 11 is a vertical-sectional view illustrating a schematic configuration of a dielectric window and a slot plate according to another exemplary embodiment.

FIG. 12 is a vertical-sectional view illustrating a schematic configuration of a dielectric window and a slot plate according to still another exemplary embodiment.

FIG. 13 is an explanatory view illustrating a schematic configuration of protrusions and slots.

FIG. 14 is a graph illustrating the absorptivity of microwave power in a case where the arrangement of the protrusions is changed.

FIG. 15 is a graph illustrating the absorptivity of microwave power in a case where the arrangement of the protrusions is changed.

FIG. 16 is a graph illustrating the absorptivity of microwave power in a case where the arrangement of the protrusions is changed.

FIG. 17 is a graph illustrating the absorptivity of microwave power in a case where the arrangement of the protrusions is changed.

FIG. 18 is an explanatory view illustrating a schematic configuration of protrusions and slots.

FIG. 19 is a graph showing the absorptivity of microwave power in a case where the arrangement of the protrusions is changed.

FIG. 20 is a graph showing the absorptivity of microwave power in a case where the arrangement of the protrusions is changed.

### DETAILED DESCRIPTION TO EXECUTE THE INVENTION

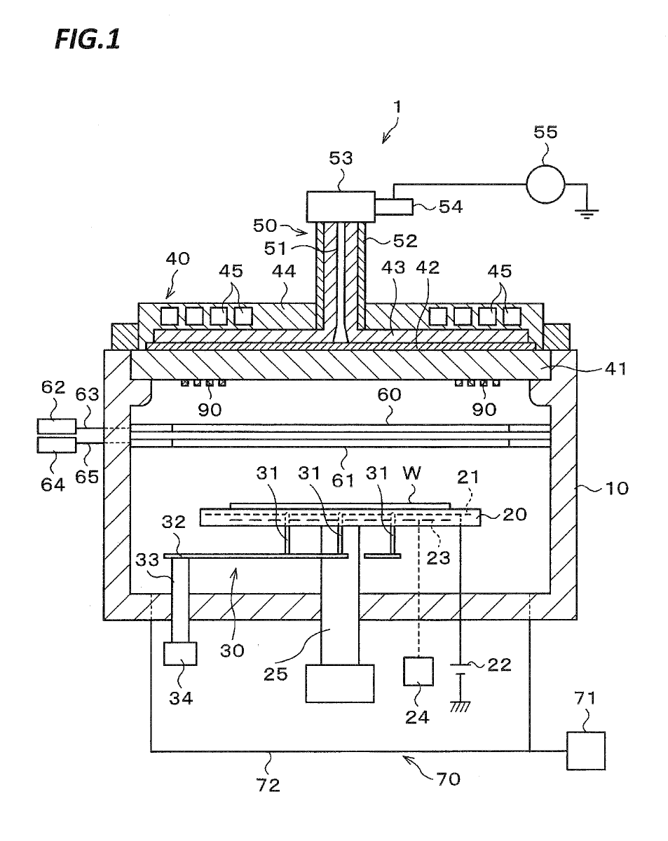

Hereinafter, exemplary embodiments of the present disclosure will be described with reference to the drawings. FIG. 1 is a vertical-sectional view illustrating a schematic configuration of a plasma processing apparatus 1 according to an exemplary embodiment of the present disclosure. The plasma processing apparatus 1 is a film forming apparatus that performs a plasma chemical vapor deposition (CVD) processing on a surface (upper surface) of the wafer W as a workpiece. The present disclosure is not limited to the following exemplary embodiments.

The substrate processing apparatus 1 includes a processing container 10 as illustrated in FIG. 1. The processing container 10 has a substantially cylindrical shape with the ceiling side opened. A radial line slot antenna 40 (to be described later) is arranged in the ceiling side opening. A carry-in/out port (not illustrated) for a wafer W is formed on the side surface of the processing chamber 10, and a gate valve (not illustrated) is provided at the carry-in/out port. And, the inside of the processing container 10 is configured to be sealable. The processing container 10 is formed of a metal such as, for example, aluminum or stainless steel. The processing container 10 is electrically grounded.

A cylindrical placing table 20 is provided at the bottom of the processing container 10 to place the wafer W on the upper surface thereof. The placing table 20 is formed of, for example, MN.

A waveguide plate 21 for an electrostatic chuck is provided inside the placing table 20. The electrode 21 is connected to a DC power source 22 provided outside the processing container 10. The wafer W may be electrostatically attracted onto the placing table 20 by generating a Johnsen-Rahbeck force on the surface of the placing table 20 by the DC power source 22.

Further, a temperature adjusting mechanism 23 is provided inside the placing table 20 to circulate, for example, a cooling medium. The temperature adjustment mechanism 23 is provided outside the processing container 10 and connected to a liquid temperature control unit 24 that adjusts the temperature of the cooling medium. Then, the temperature of the coolant medium is adjusted by the liquid temperature control unit 24, so that the temperature of the placing table 20 may be controlled. As a result, the wafer W placed on the placing table 20 may be maintained at a predetermined temperature.

Further, the placing table 20 may be connected with a high frequency power source for RF bias (not illustrated). The high frequency power source outputs high frequency waves of a constant frequency suitable for controlling the energy of the ions drawn into the workpiece W, for example, 13.56 MHz at a predetermined power.

Further, for example, three through-holes (not illustrated) are formed on the placing table 20 to penetrate the placing table 20 in the thickness direction. In the through-holes, lift pins 31 (to be described later) are provided so as to be inserted therethrough.

A support member 25 is provided on the lower surface of the placing table 20 to support the placing table 20.

A lift mechanism 30 is provided below the placing table 20 to move up and down the wafer W placed on the placing table 20. The lift mechanism 30 includes lift pins 31, a plate 32, a support column 33, and a lift driving unit 34. For example, three lift pins 31 are provided on the upper surface of the plate 32 and configured to protrude from the upper surface of the placing table 20. The plate 32 is supported by the upper end of the support column 33 penetrating the bottom surface of the processing container 10. The lift driving unit 34 disposed outside the processing container 10 is provided at the lower end of the support column 33. Through the operation of the lift driving unit 34, the three lift pins 31 penetrating the placing table 20 are moved up and down to switch between a state where the upper ends of the lift pins 31 protrude upward from the upper surface of the placing table 20 and a state where the upper ends of the lift pins 31 are drawn into the placing table 20.

A radial line slot antenna 40 is provided in the ceiling side opening of the processing container 10 to supply microwaves for plasma generation. The radial line slot antenna 40 includes a dielectric window 41, a slot plate 42, a slow-wave plate 43, and a shield cover 44.

The dielectric window 41 is provided to seal the ceiling side opening of the processing container 10 through a sealing member such as, for example, an O-ring (not illustrated). Accordingly, the inside of the processing container 10 is air-tightly maintained. The dielectric window 41 is formed of a dielectric such as, for example, quartz, Al₂O₃, or AlN. The dielectric window 41 transmits the microwaves. Details of the dielectric window 41 will be described later.

The slot plate 42 is provided as a top surface of the dielectric window 41 to face the placing table 20. The slot plate 42 is formed of a conductive material such as, for example, copper, aluminum, or nickel. Details of the slot plate 42 will be described later.

The slow-wave plate 43 is provided on the top surface of the slot plate 42. The slow-wave plate 43 is formed of a low-loss dielectric material such as, for example, quartz, Al₂O₃ or AlN. The slow-wave plate 43 shortens the wavelength of the microwaves.

The shield cover 44 is provided on the top surface of the slow-wave plate 43 to cover the slow-wave plate 43 and the slot plate 42. A plurality of annular flow paths 45 are provided inside the shield cover 44 to circulate, for example, a cooling medium. The dielectric window 41, the slot plate 42, the slow-wave plate 43, and the shield cover 44 are adjusted to a predetermined temperature by the cooling member flowing through the flow paths 45.

A coaxial waveguide 50 is connected to a central portion of the shield cover 44. The coaxial waveguide 50 includes an inner conductor 51 and an outer pipe 52. The inner conductor 51 is connected to the slot plate 42. The lower end portion of the inner conductor 51 is conically formed and has a tapered shape in which its diameter expands toward the slot plate 42 side. The lower end portion makes it possible to efficiently propagate the microwaves to the slot plate 42.

The coaxial waveguide 50 is connected with a mode converter 53 that converts microwaves into a predetermined oscillation mode, a rectangular waveguide 54, and a microwave generator 55 that generates microwaves, in this order from the coaxial waveguide 50 side. The microwave generator 55 generates microwaves of a predetermined frequency, for example, 2.45 GHz.

With the configuration, the microwaves generated by the microwave generator 55 are propagated sequentially through the rectangular waveguide 54, the mode converter 53, and the coaxial waveguide 50, supplied into the radial line slot antenna 40, and compressed by the slow-wave plate 43 to have a shorter wavelength. Then, circularly polarized waves are generated from the slot plate 42, transmitted through the microwave transmitting plate 41, and radiated into the processing container 10. A processing gas is converted into plasma in the processing container 10 by the microwaves, and the plasma processing of the wafer W may be performed by the plasma.

In the processing container 10, an upper shower plate 60 and a lower shower plate 61 are provided in the upper portion of the placing table 20. The upper shower plate 60 and the lower shower plate 61 are formed of a hollow tube material made of, for example, a quartz tube. In the upper shower plate 60 and the lower shower plate 61, a plurality of openings (not illustrated) are distributed to supply a gas to the wafer W on the placing table 20.

The upper shower plate 60 is connected with a plasma generation gas supply source 62 disposed outside the processing container 10, via a pipe 63. The plasma generation gas supply source 62 stores, for example, Ar gas as a gas for plasma generation. The plasma generation gas is introduced from the plasma generation gas supply source 62 into the upper shower plate 60 through the pipe 63. Thus, the plasma generation gas is supplied in a state of being uniformly dispersed in the processing container 10.

The upper shower plate 61 is connected with a processing gas supply source 64 disposed outside the processing container 10, via a pipe 65. The processing gas supply source 64 stores a processing gas corresponding on the film to be formed. For example, in a case of forming a SiN film on the surface of the wafer W, trisilylamine (TSA), N₂ gas, and H₂ gas are stored as processing gases. In a case of forming a SiO₂ film, TEOS is stored. The processing gas is introduced from the processing gas supply source 64 into the lower shower plate 61 through the pipe 65. Thus, the processing gas is supplied in a state of being uniformly dispersed in the processing container 10.

A decompression mechanism 70 is provided on the bottom surface of the processing container 10 to decompress the atmosphere inside the processing container 10. The decompression mechanism 70 has a configuration in which, for example, an exhaust unit 71 having a vacuum pump is connected to the bottom surface of the processing chamber 10 via an exhaust pipe 72. The exhaust unit 71 may exhaust the atmosphere in the processing container 10 and reduce the pressure to a predetermined vacuum degree.

Next, detailed configurations of the dielectric window 41 and the slot plate 42 will be described.

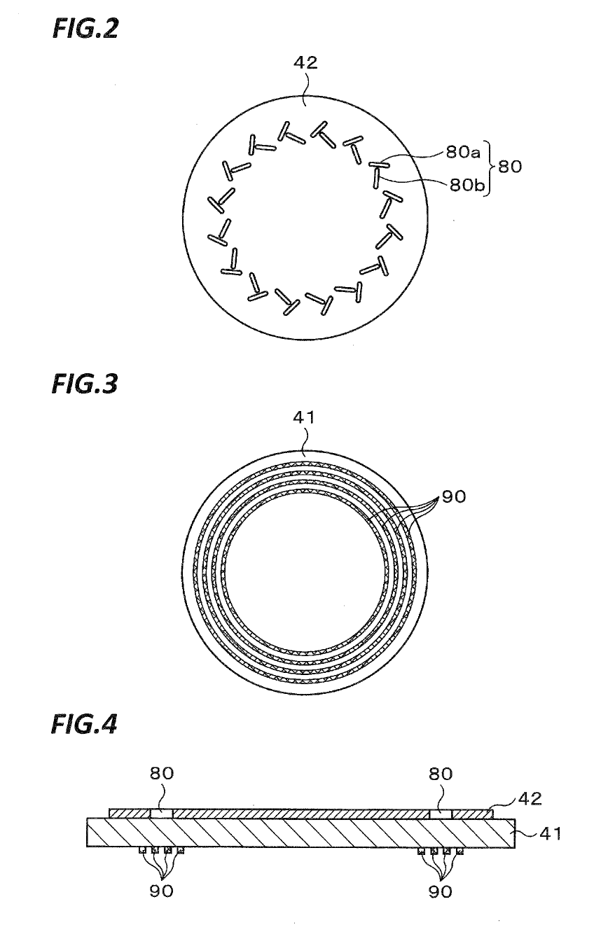

As illustrated in FIG. 2, the slot plate 42 has a substantially disk shape. The slot plate 42 includes a plurality of slots 80 formed therein to radiate microwaves. That is, the slot plate 42 functions as an antenna. The plurality of slots 80 are formed concentrically with the slot plate 42, and are arranged at predetermined intervals in the circumferential direction. Each slot 80 has two slot holes 80a, 80b formed by, for example, an elongated hole or slit. The slot hole 80a and the slot hole 80b are formed and arranged so as to extend in a direction intersecting with each other or orthogonal to each other.

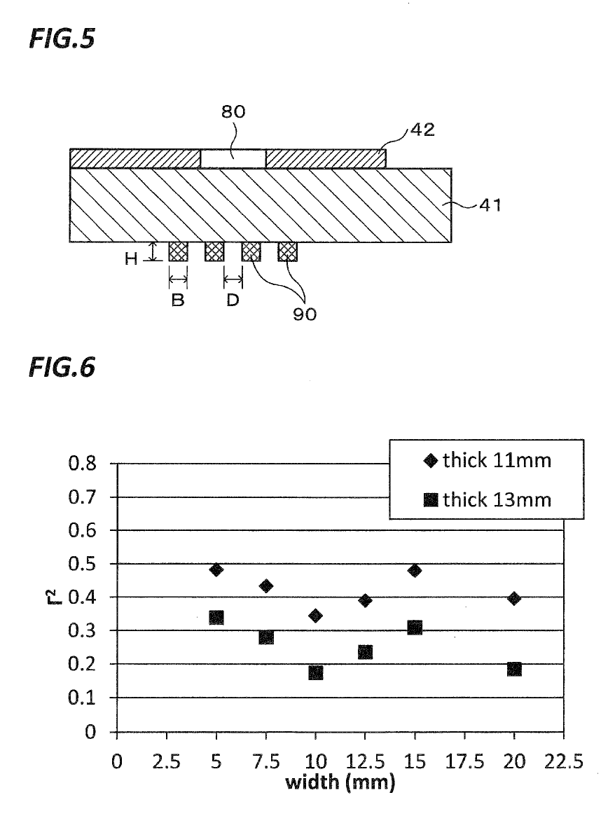

As illustrated in FIGS. 3 and 4, the dielectric window 41 has a substantially disk shape with a flat bottom surface. A plurality of (e.g., four) annular protrusions 90 are provided on the lower surface of the dielectric window 41 to protrude downward from the lower surface. The plurality of protrusions 90 are formed concentrically with the slot plate 42, and are arranged at predetermined intervals in the radial direction. Further, the plurality of protrusions 90 are arranged at a position corresponding to the slot 80 of the slot plate 42, that is, below the slots 80. As illustrated in FIG. 5, a width B of each protrusion 90 is λ/4±λ/8 with respect to the wavelength λ of the microwaves.

Next, descriptions will be made on the plasma processing of the wafer W to be performed by the plasma processing apparatus 1 configured as described above.

First, the wafer W carried into the processing container 10 is placed on the placing table 20 by the lift pins 31. At this time, the DC power source 22 is turned on to apply a DC voltage to the electrode 21 of the placing table 20, so that the wafer W is attracted and held by the placing table 20.

Thereafter, the inside of the processing container 10 is sealed. Then, the atmosphere in the processing container 10 is decompressed to a predetermined pressure, for example, 400 mTorr (=53 Pa) by the exhaust mechanism 70. Further, the plasma generating gas is supplied from the upper shower plate 60 into the processing container 10, and the processing gas for plasma film formation is supplied from the lower shower plate 61 into the processing container 10.

When the plasma generation gas and the processing gas are supplied into the process container 10 in this manner, the microwave generator 55 is operated. Thus, the microwave generator 55 generates microwaves of a predetermined power at a frequency of, for example, 2.45 GHz. An electric field is generated on the bottom surface of the dielectric window 41, so that the plasma generating gas is converted into plasma, and the processing gas is converted into plasma. Then, the film forming processing is performed on the wafer W by the active species generated at that time. Thus, a predetermined film is formed on the surface of the wafer W.

Thereafter, when a predetermined film is grown and a film having a predetermined film thickness is formed on the wafer W, the supply of the plasma generation gas and the processing gas and the irradiation of the microwaves are stopped. Thereafter, the wafer W is carried out from the processing container 10, and a series of the plasma processing is completed.

According to the above exemplary embodiment, since the width B of each protrusion 90 of the dielectric window 41 is λ/4±λ/8, it is possible to improve the absorption of the microwave power into the plasma, thereby suppressing the reflected waves.

Here, the effect of the width B of the protrusions 90 will be described in detail. The present inventors performed a simulation using the plasma processing apparatus 1 to investigate the condition of the protrusions 90 for achieving this effect. In the simulation, the effect was verified with respect to the width B, the distance D, and the height H of the protrusions 90 illustrated in FIG. 5. The distance D is a distance between adjacent protrusions 90. In the simulation, the wavelength λ of the microwaves is 40 mm.

In the simulation, the square of the reflection coefficient of microwaves (Γ²) is used as an indicator of the absorptivity of the microwave power to be evaluated. In addition, the average value of Γ² when the electron density was changed from 1e+17 to 1e+18 (/m³) was used as a representative value of the simulation. Specifically, when the electron density is in a range of 1e+17 to 4e+17 (/m³), the power absorption is large, so that Γ² tends to fluctuate. Thus, the calculation was performed with a step width of 0.3e+17 (/m³). Further, when the electron density is in a range of 4e+17 to 1e+18 (/m³), the fluctuation of Γ² is relatively small. Thus, it was calculated with a step width of 1e+17 (/m³). As a result of calculating the average value of these Γ², the average value was 0.6, which was taken as a representative value of Γ². Therefore, in the simulation, when Γ² is smaller than 0.6, it shows that the absorption of the microwave power is improved.

The first verification result of the width B of the protrusions 90 will be described. The conditions of the simulation are as follows. There were two kinds of dielectric windows 41 whose thicknesses were 11 mm and 13 mm. The number of the protrusions 90 was four. The distance D between the protrusions 90 was 10 mm, and the height H was 5 mm. In addition, the width B of the protrusions 90 was changed within a range of 5 to 20 mm.

The result of the simulation is shown in FIG. 6. In FIG. 6, the horizontal axis represents the width B of the protrusions 90 and the vertical axis represents the square of the reflection coefficient of the microwaves (Γ²). Referring to FIG. 6, in either case where the thickness of the dielectric window 41 is 11 mm or 13 mm, Γ² becomes smaller than the representative value when the width B is 10 mm, that is, λ/4, and the absorptivity of the microwave power is the best. Therefore, it was found that the optimum value of the width B is λ/4.

As a result of intensive studies by the present inventors, it has been found that when the width B of the protrusions 90 is within the range of λ/4 to ±λ/8, there is a sufficient effect of improving the absorptivity of the microwave power. That is, the width B is appropriately λ/4±λ/8.

The second verification result of the distance D of the protrusions 90 will be described. The conditions of the simulation are as follows. There were two kinds of dielectric window 41 whose thicknesses were 11 mm and 13 mm. The number of the protrusions 90 was four. The width B of the protrusions 90 was 10 mm, and the height H was 5 mm. In addition, the distance D between the protrusions 90 was changed within a range of 5 to 20 mm.

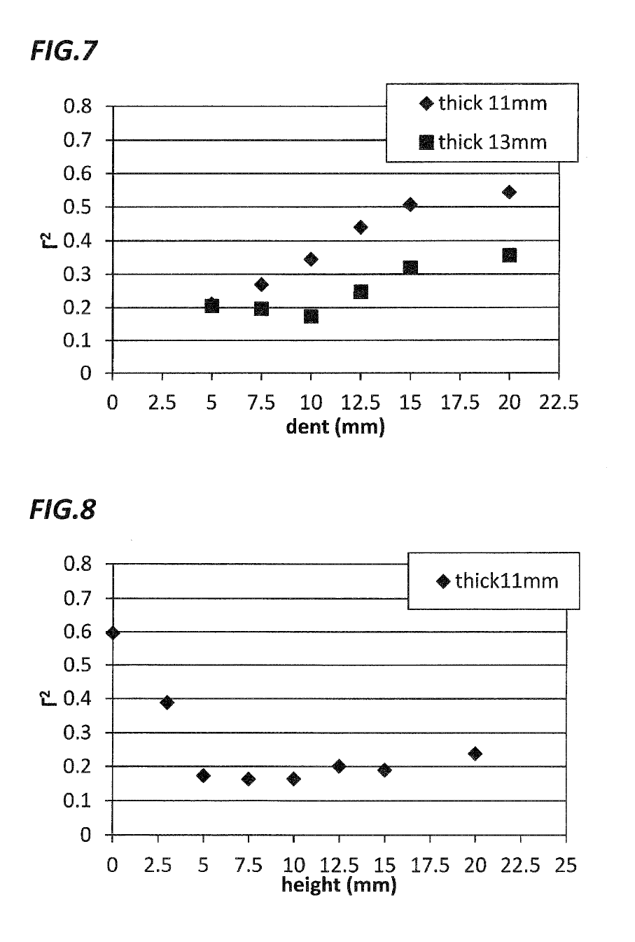

The result of the simulation is shown in FIG. 7. In FIG. 7, the horizontal axis represents the distance D between the protrusions 90 and the vertical axis represents the square of the reflection coefficient of the microwaves (Γ²). Referring to FIG. 7, when the thickness of the dielectric window 41 is 11 mm, the optimum value of the interval D is 5 mm, whereas when the thickness of the dielectric window 41 is 13 mm, the optimum value of the interval D is 10 mm. Therefore, the optimum value of the distance D depends at least on the thickness of the dielectric window 41, and there is no universal optimum value for obtaining a sufficient effect at a specific distance D. In other words, the absorptivity of the microwave power does not depend on the distance D between the protrusions 90, and the protrusions 90 may be periodically provided at regular intervals, or alternatively, the protrusions 90 may be aperiodically provided at different intervals. In the invention described in Patent Document 1 described above, it is essential to periodically form concavo-convex portions including protrusions at a pitch of 7.5 to 30 mm. However, it is a new finding obtained by the present inventors that the distance D between the protrusions 90 is not limited and may be arbitrarily set in this manner.

The third verification result of the height H of the protrusions 90 will be described. The conditions of the simulation are as follows. The dielectric window 41 had a thickness of 11 mm. The number of the protrusions 90 was four. The width B of the protrusions 90 was 10 mm, and the distance D was 5 mm. In addition, the height H of the protrusions 90 was changed within a range of 0 to 20 mm.

The result of the simulation is shown in FIG. 8. In FIG. 8, the horizontal axis represents the height H of the protrusions 90 and the vertical axis represents the square of the reflection coefficient of the microwaves (Γ²). Referring to FIG. 8, the absorptivity of the microwave power is improved up to the height H of 5 mm, but the power absorption does not change when the height H is 5 mm or more. Therefore, also for the height H, there is no universal optimum value for obtaining a sufficient effect at a specific height H.

As seen from the simulation described above, the condition for improving the microwave power absorption to the plasma and suppressing the reflected waves from the plasma to the slots is that the width B of the protrusions 90 is λ/4±λ/8. In addition, according to the exemplary embodiment, the reflected waves from the plasma to the slots 80 may be suppressed, and thus, the circumferential bias of the plasma distribution may be suppressed so that the plasma distribution becomes uniform.

Further, when the width B of the protrusions 90 is λ/4±λ/8, a mode jump may be suppressed. That is, as the microwave power absorption improves, the microwave reflection coefficient decreases. In addition, the reflection coefficient of the microwaves is linearly changed with respect to a change in the electron density. Thus, it is possible to suppress a sharp drop of the reflection coefficient, so that a mode jump is suppressed. As described above, the mode jump is also one of causes of the circumferential bias of the plasma distribution. Thus, according to the exemplary embodiment, the circumferential bias of the plasma distribution may be further suppressed.

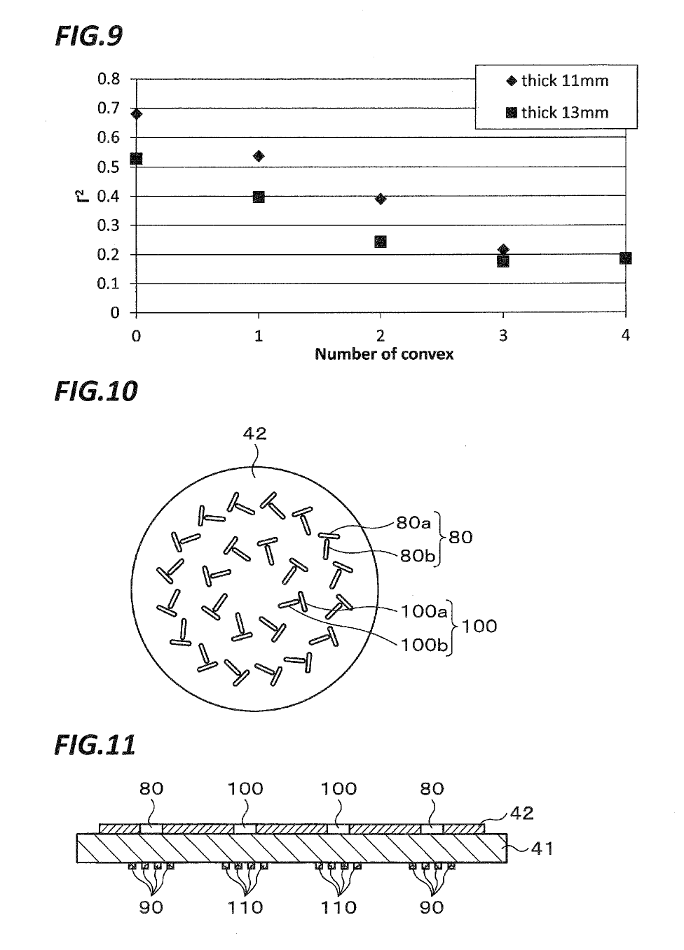

In the exemplary embodiment, four protrusions 90 are provided on the lower surface of the dielectric window 41, but the number of the protrusions 90 is not limited thereto and may be set arbitrarily. FIG. 9 is a graph illustrating a result of the simulation performed by the inventors in which the number of the protrusions 90 is changed. In FIG. 9, the horizontal axis represents the number of the protrusions 90 and the vertical axis represents the square of the reflection coefficient of the microwaves (Γ²). In the simulation, the dielectric window 41 had a thickness of 11 mm or 13 mm. The width B of the protrusions 90 was 10 mm, the distance D was 5 mm, and the height H was 5 mm. In addition, the number of the protrusions 90 was changed within a range of 1 to 4.

Referring to FIG. 9, even when the number of the protrusions 90 is one, Γ² is smaller than the representative value. For this reason, it was found that the absorptivity of the microwave power is improved, and thus, the circumferential bias of the plasma distribution may be suppressed. Furthermore, it was also found that as the number of the protrusions 90 increases, the effect increases.

In the exemplary embodiments described above, a plurality of slots 80 are formed on one circumference on the slot plate 42. However, the number of circumferences is not limited thereto but may be arbitrarily set. For example, as illustrated in FIG. 10, a plurality of other slots 100 may be formed inside the plurality of slots 80. The plurality of other slots 100 are formed concentrically with the slot plate 42, and are arranged at predetermined intervals in the circumferential direction. Similarly to the slots 80, each slot 100 has two slot holes 100a, 100b.

In such a case, as illustrated in FIG. 11, a plurality of (e.g., four) annular protrusions 110 are provided at a position corresponding to the slot 100 on the lower surface of the dielectric window 41, that is, below the slot 100. The plurality of protrusions 110 are formed concentrically with the slot plate 42, and are arranged at predetermined intervals in the radial direction. Further, similarly to the protrusions 90, the width of each protrusion 110 is λ/4±λ/8 with respect to the wavelength λ of the microwaves.

Also in this exemplary embodiment, it is possible to achieve the effects of the above-described exemplary embodiment. Therefore, the circumferential bias of the plasma distribution may be suppressed.

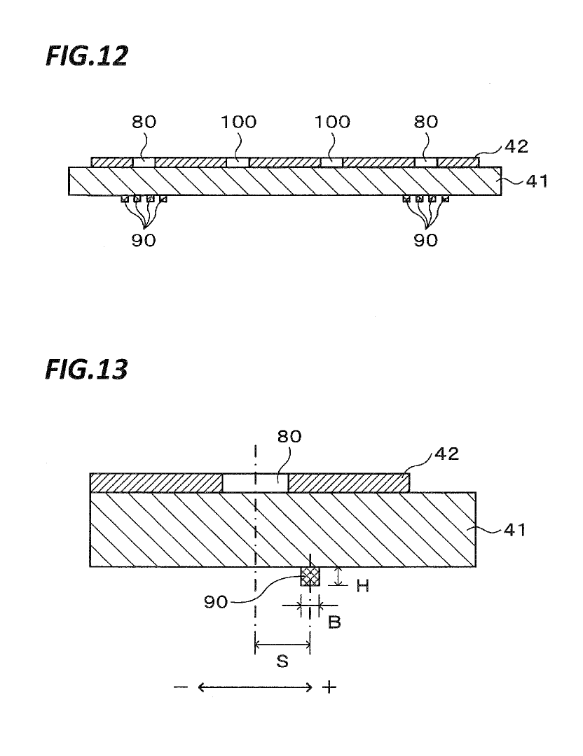

On the lower surface of the dielectric window 41, the protrusions 90, 110 are not necessarily provided corresponding to all the slots 80, 100. For example, as illustrated in FIG. 12, only the protrusions 90 corresponding to the slot 80 may be provided, and the protrusions 110 corresponding to the slot 100 may be omitted.

Further, in the exemplary embodiments described above, a plurality of slots 80, 100 are formed on the slot plate 42 concentrically with the slot plate 42. However, the arrangement of the slots is not limited thereto and may be arbitrarily set. For example, slots may be dotted in the slot plate 42. In such a case, protrusions having a width of) λ/4±λ/8 are formed at positions corresponding to the respective slots.

As a result of further intensive studies, the inventors have found a suitable arrangement of the protrusions 90 with respect to the slot 80. That is, as illustrated in FIG. 13, it is found that when the protrusion 90 is provided at a position where a distance S between the center of the protrusion 90 and the center of the slot 80 is not more than λ/2, the absorptivity of the microwave power to the plasma is improved.

The effect of the arrangement of the protrusions 90 will be described in detail. The present inventors performed a simulation using the plasma processing apparatus 1 to investigate the arrangement of the protrusions 90 for achieving this effect. In the simulation, the maximum intensity of the electric field generated at the lower surface of the dielectric window 41, that is, the electric field intensity at the slot 80 is used as an index of the absorptivity of the microwave power to be evaluated. In addition, the electric field intensity when the electron density was changed from 1e+17 to 1e+18 (/m³) was calculated. In the simulation, the wavelength λ of the microwaves is 40 mm.

The conditions of the simulation are as follows. The dielectric window 41 had a thickness of 5 mm. The number of the protrusions 90 with respect to the slot 80 was one. The height H of the protrusion 90 was 5 mm, and the width B was set to two widths of 5 mm and 10 mm. Then, the distance S was changed in an order of 0 mm, ±5 mm, ±10 mm, ±15 mm, and ±20 mm. Further, as a comparative example, a simulation was also performed in which the protrusion 90 is not present (that is, a case where the lower surface of the dielectric window 41 is flat). In the symbol “±” of the distance S, “+” indicates a direction away from the center of the dielectric window 41 (+ in FIG. 13), and “−” indicates a direction approaching the center of the dielectric window 41 (− in FIG. 13).

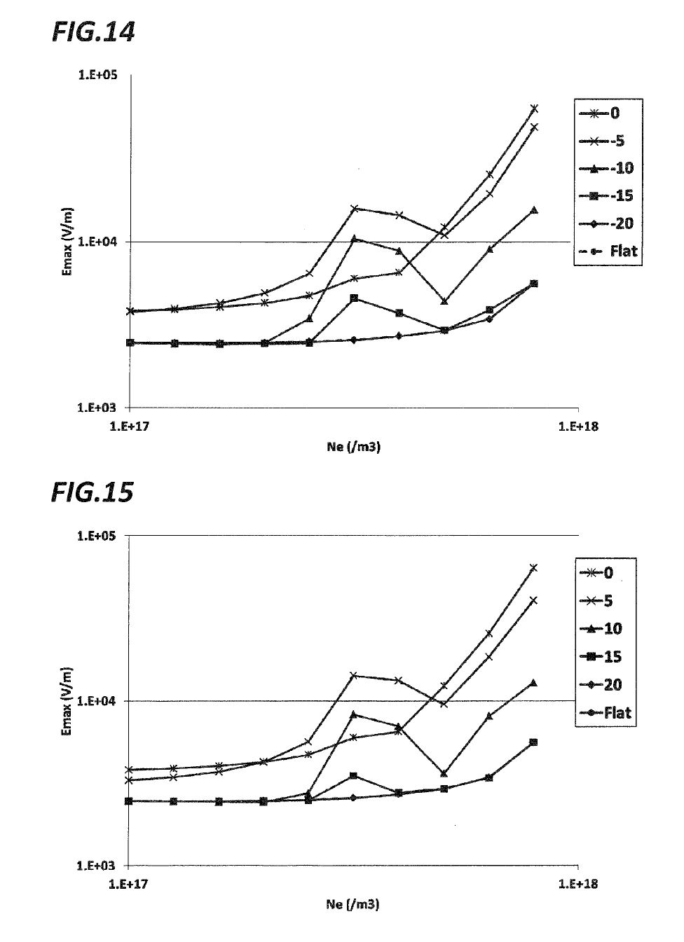

FIG. 14 illustrates a simulation result when the protrusion 90 is shifted in the “−” direction in the case where the width B of the protrusion 90 is 5 mm. FIG. 15 illustrates a simulation result when the protrusion 90 is shifted in the “+” direction in the case where the width B of the protrusion 90 is 5 mm. In FIGS. 14 and 15, the horizontal axis represents an electron density and the vertical axis represents an electric field intensity. Referring to FIGS. 14 and 15, when the protrusion 90 is provided at a position where the distance S is within 20 mm, that is, within λ/2, the electric field intensity becomes larger than the case where the protrusion 90 is not provided. Therefore, it is possible to improve the absorptivity of the microwave power to the plasma. In addition, when the distance S is larger than 20 mm, the electric field intensity is equal to that in the case where the protrusion 90 is not provided. Therefore, the distance S is appropriately within λ/2.

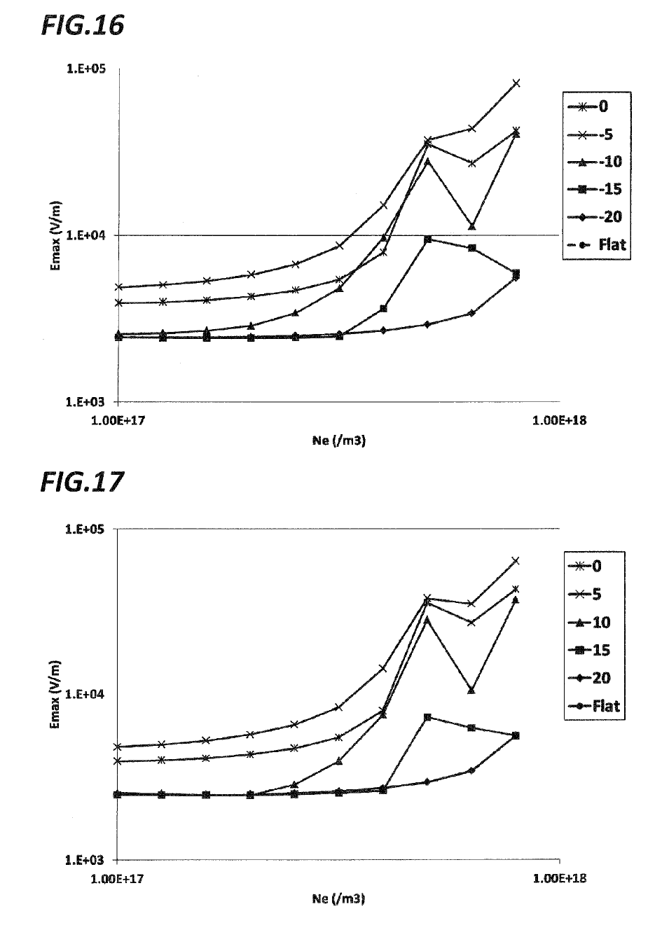

FIG. 16 illustrates a simulation result when the protrusion 90 is shifted in the “−” direction in the case where the width B of the protrusion 90 is 10 mm. FIG. 17 illustrates a simulation result when the protrusion 90 is shifted in the “+” direction in the case where the width B of the protrusion 90 is 10 mm. In FIGS. 16 and 17, the horizontal axis represents an electron density and the vertical axis represents an electric field intensity. Even in this case, when the protrusion 90 is provided at a position where the distance S is within 20 mm, that is, within λ/2, the electric field intensity becomes larger than the case where the protrusion 90 is not provided. Therefore, it is possible to improve the absorptivity of the microwave power to the plasma.

By the simulation described above, it is found that when the protrusion 90 is provided at a position where a distance S between the center of the protrusion 90 and the center of the slot 80 is not more than λ/2, the absorptivity of the microwave power to the plasma may be improved. In addition, the reflected waves from the plasma to the slots 80 may be suppressed, and the mode jump may also be suppressed. Thus, the circumferential bias of the plasma distribution may be suppressed so that the plasma distribution becomes uniform.

In addition, comparing the case where the width B of the protrusions 90 is 5 mm and the case where the width B of the protrusions is 10 mm, the electric field intensity may be increased in the case where the width B is 10 mm, that is, λ/4. Therefore, when the protrusions 90 are provided at a position where the distance S is equal to or less than λ/2 and the width of the protrusions 90 is set to λ/4, the absorptivity of the microwave power to the plasma may be further improved.

As a result of intensive studies by the present inventors, it has been found that when the width B of the protrusions 90 is within the range of λ/4 to ±λ/8, there is a sufficient effect of improving the absorptivity of the microwave power. That is, the width B is appropriately λ/4±λ/8.

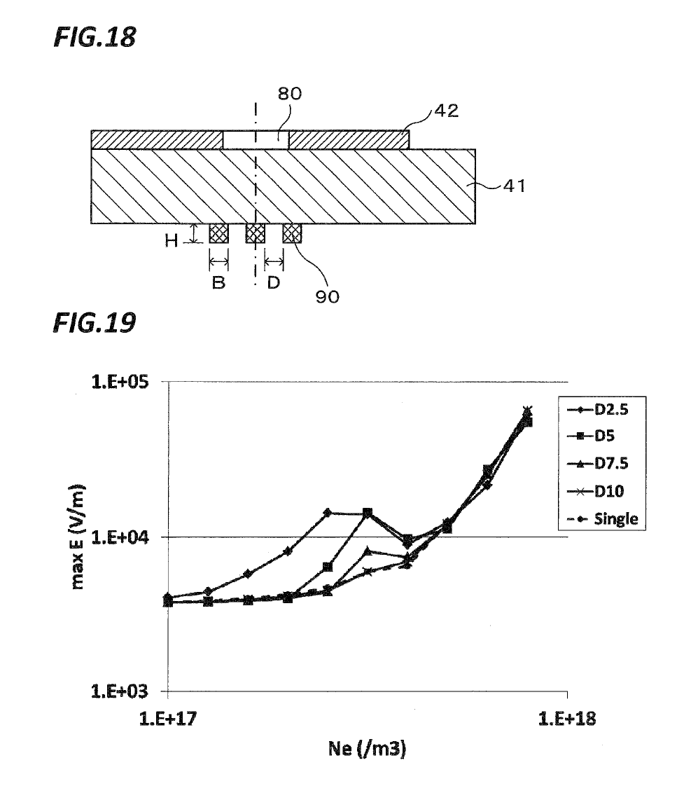

Next, descriptions will be made on a case where a plurality of (e.g., three) protrusions 90 are provided for the slot 80 as illustrated in FIG. 18. Among the three protrusions 90, the middle protrusion 90 is provided on the center line of the slot 80 (that is, the distance S is 0 mm), and protrusions 90 are provided on both sides thereof at a distance D.

The inventors calculated the electric field intensity when the electron density was changed from 1e+17 to 1e+18 (/m³) in the same manner as in the above simulation. The conditions of the simulation are as follows. The dielectric window 41 had a thickness of 5 mm. The height H of the protrusion 90 was 5 mm, and the width B was set to two widths of 5 mm or 10 mm. Then, the distance D was changed in an order of 0 mm, 5 mm, 7.5 mm, and 10 mm. Further, as a comparative example, a simulation in a case where one protrusion 90 was provided was also performed.

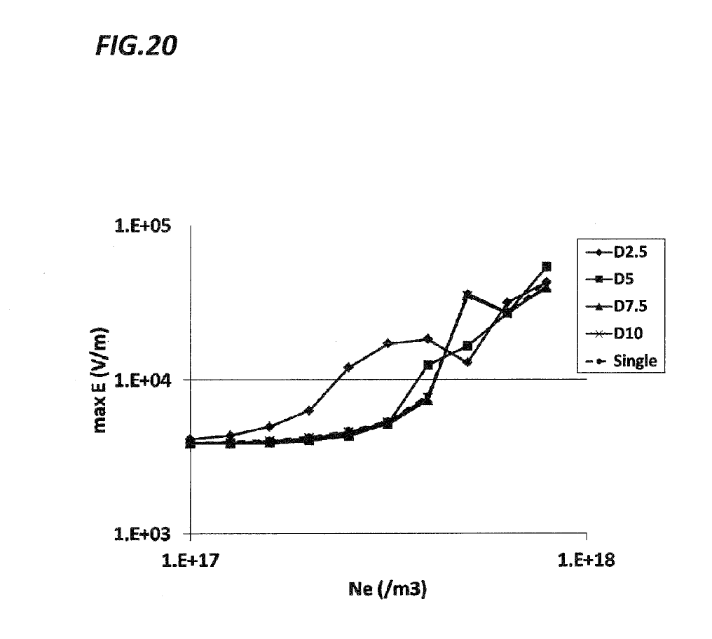

FIG. 19 illustrates a simulation result in the case where the width B of the protrusion 90 is 5 mm. FIG. 20 illustrates a simulation result in the case where the width B of the protrusion 90 is 10 mm. In FIGS. 19 and 20, the horizontal axis represents an electron density and the vertical axis represents an electric field intensity. Referring to FIGS. 19 and 20, in either case where the width B of the protrusion 90 is 5 mm or 10 mm, as the distance D between the protrusions 90 is widened, the electric field intensity approaches the electric field intensity in the case where there is only one protrusion 90. Therefore, it has been found that when the protrusions 90 are provided sufficiently away from the slot 80, the protrusions 90 do not contribute to the improvement of electric field intensity.

Further, in the above exemplary embodiment, the present disclosure is applied to the plasma processing for performing the film formation processing, but the present disclosure may also be applied to a plasma processing for performing a substrate processing other than the film formation processing (e.g., an etching processing or a sputtering).

Further, the substrate to be processed by the plasma processing of the present disclosure may be any substrate such as, for example, a semiconductor wafer, an organic EL substrate, or a substrate for flat panel display (FPD).

Although exemplary embodiments of the present disclosure have been described with reference to the accompanying drawings, the present disclosure is not limited thereto. It should be understood that various modifications or changes that can be easily inferred by those skilled in the art within the scope and spirit described in the claims fall within the scope of the present disclosure.

### DESCRIPTION OF SYMBOLS

| | |
|---|---|
| 1: plasma processing apparatus | 10: processing container |
| 40: radial line slot antenna | 41: dielectric window |
| 42: slot plate | 80, 100: slot |
| 90, 110: protrusion | W: wafer |

What is claimed is:

1. A plasma processing apparatus for performing a plasma processing on a workpiece, the apparatus comprising:
a processing container that accommodates the workpiece;
a dielectric window that is provided to seal an opening in an upper portion of the processing container and transmits microwaves into the processing container; and
a slot plate that is provided on an upper surface of the dielectric window and has a plurality of slots formed to radiate the microwaves to the dielectric window,
wherein the dielectric window includes a protrusion protruding downward from a lower surface of the dielectric window at a position corresponding to each of the slots, and
a width of the protrusion is λ/4±λ/8 with respect to a wavelength 2 of the microwaves.

2. The plasma processing apparatus of claim 1, wherein a plurality of protrusions are provided on the lower surface of the dielectric window.

3. A plasma processing apparatus for performing a plasma processing on a workpiece, the apparatus comprising:
a processing container that accommodates the workpiece;
a dielectric window that is provided to seal an opening in an upper portion of the processing container and transmits microwaves into the processing container; and
a slot plate that is provided on an upper surface of the dielectric window and has a plurality of slots formed to radiate the microwaves to the dielectric window,
wherein the dielectric window includes a protrusion protruding downward from a lower surface of the dielectric window at a position where a distance between a center of the protrusion and a center of each of the slots is equal to or less than λ/2 with respect to a wavelength λ of the microwaves.

4. The plasma processing apparatus of claim 3, wherein a width of the protrusion is λ/4±λ/8.

5. The plasma processing apparatus of claim 3, wherein a plurality of protrusions are provided on the lower surface of the dielectric window.
